(19) United States
(12) Patent Application Publication
(10) Pub. No.: US 2026/0153566 A1
(43) Pub. Date: Jun. 4, 2026

(54) DETERMINING THE HEALTH OF A POWER SOURCE BASED ON CHARGING EVENTS AND STATES OF CHARGE

(71) Applicants: VOLKSWAGEN AKTIENGESELLSCHAFT, WOLFSBURG (DE); The Board of Trustees of the Leland Stanford Junior University, Stanford, CA (US)

(72) Inventors: Pietro Bosoni, Menlo Park, CA (US); Andrea Lanubile, Menlo Park, CA (US); Gabriele Pozzato, Palo Alto, CA (US); William Paxton, Redwood City, CA (US); Simona Onori, Palo Alto, CA (US)

(21) Appl. No.: 18/968,745

(22) Filed: Dec. 4, 2024

(51) Int. Cl. G01R 31/392; G01R 31/367; G01R 31/387

(52) U.S. Cl. CPC G01R 31/392; G01R 31/367; G01R 31/387

(57) ABSTRACT

A method is provided. The method includes identifying a beginning state of charge and an ending state of charge for a charging event for a battery. The method also includes identifying a set of state of charge ranges based on the beginning state of charge and the ending state of charge. The method further includes identifying a set of machine learning models based on the set of state of charge ranges. Each machine learning model is associated with a respective state of charge range. The method further includes determining an estimated health for the battery based on the set of machine learning models and one or more sets of charging records for the battery.

### TECHNICAL FIELD

Aspects of the present disclosure relate to a battery management system for determining the health of a power source (e.g., a battery), and more particularly, to a battery management system for determining the health of the power source based on charging events and states of charge.

### BACKGROUND

Various devices (e.g., smart phones, computing devices, laptop computers, tablet computers, etc.) and apparatuses (e.g., vehicles) may use a power source to operate. For example, a vehicle may use a battery, fuel, a fuel cell, or some other power source to power the components of the vehicle and/or to move the vehicle. As the battery is discharged (to provide power to the vehicle) and charged, the battery may age. As the battery ages, the performance of the battery may degrade. For example, the capacity (e.g., the power/storage capacity) of the battery may decrease, and/or the amount of power provided by the battery may decrease.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a block diagram that illustrates an example vehicle, in accordance with one or more embodiments of the present disclosure.

FIG. 2 is a diagram illustrating an example battery management system, in accordance with one or more embodiments of the present disclosure.

FIG. 3 is a block diagram that illustrates an example system architecture, in accordance with some embodiments of the present disclosure.

FIG. 4 is a diagram that illustrates example charging events, in accordance with some embodiments of the present disclosure.

FIG. 5 is a diagram illustrating example charging records, in accordance with one or more embodiments of the present disclosure.

FIG. 6 is a flow diagram of a method for determining a health of a power source, in accordance with one or more embodiments of the present disclosure.

FIG. 7 is a block diagram of an example computing device that may perform one or more of the operations described herein, in accordance with some embodiments of the present disclosure.

### DETAILED DESCRIPTION

As discussed above, when a power source, such as a battery, is discharged (to provide power to a device/apparatus, such as a vehicle) and charged, the battery may age. As the battery ages, the battery may require more voltage/current to charge, the capacity (e.g., the power capacity) of the battery may decrease, and/or the amount of power provided by the battery may decrease. The health of the battery (e.g., a state of health) may quantify an aging level for a battery in terms of changes in capacity (e.g., a decrease in capacity) and/or changes in internal resistance (e.g., increase in resistance). Determining the health of the battery may be useful and/or important for improving battery life, understanding battery operation, and gaining increased performance from the battery.

While the health of a battery may be measured with sufficient accuracy from lab tests, it is difficult to determine the health of a battery while the battery is in use (e.g., while the battery is installed in a device, such as a vehicle). For example, it may be difficult to determine the health of the battery while the battery is being charged and/or discharged (e.g., when power from the battery is used to drive a vehicle, power electronics, etc.). Because it is difficult to determine the health of the battery while the battery is in use (e.g., is charging/discharging), it may be difficult to determine the health of the battery and/or changes to the health of the battery that occur after a battery has been charged (e.g., after a charging event).

The examples, implementations, and/or embodiments described herein may be used to determine the health of a power source, such as a battery, and/or changes to the health of the power source (e.g., a decrease in health) after a charging event occurs. A charging event may refer to an event, occurrence, period of time, etc., when power/energy is being provided to a power source (e.g., a battery). For example, the period/amount of time that a battery is plugged into a power source may be referred to as a charging event. In another example, the change in state of charge of the power source may also be referred to as a charging event.

Charging events may often be inconsistent and/or random. For example, a user may start charging the power source at random states of charge. In another example, a user may not stop charging the power source at a same state of charge (e.g., the user may not always charge to a target state of charge, such as 90%). This may be due to various factors, such as the time that a power supply is available to a user, how much and/or how often, the power source is used, etc. Because the time, duration, and states of charge for different charging events may be inconsistent and/or random, it may be difficult to determine a health of the power source after charging events.

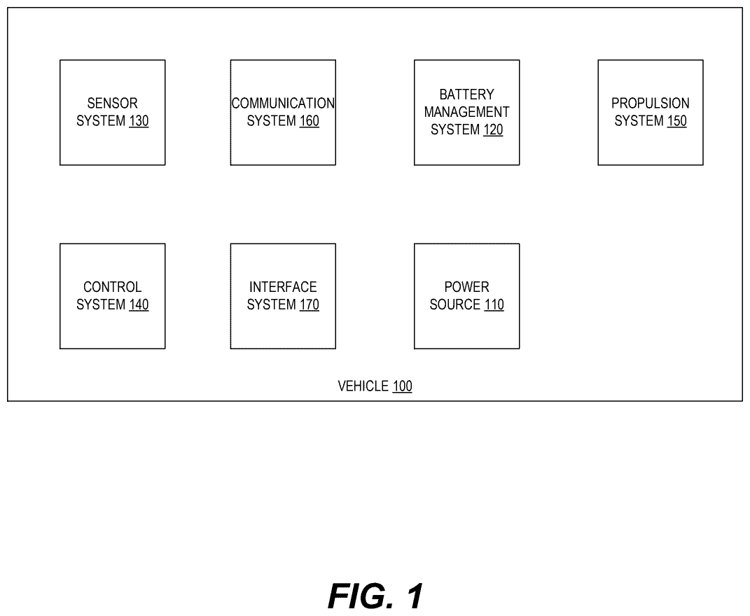

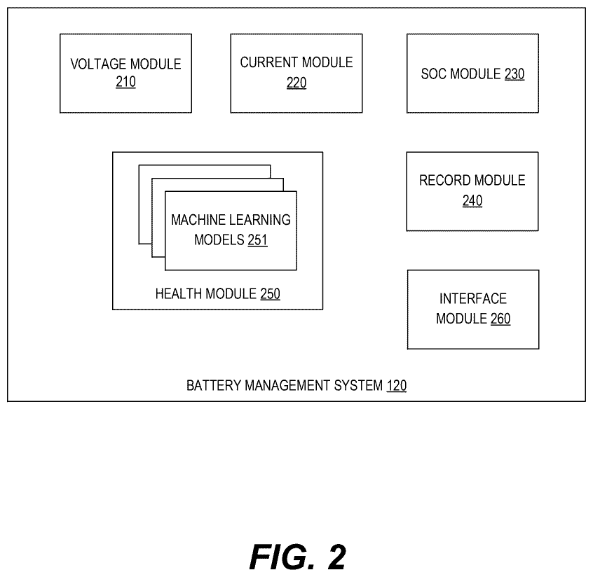

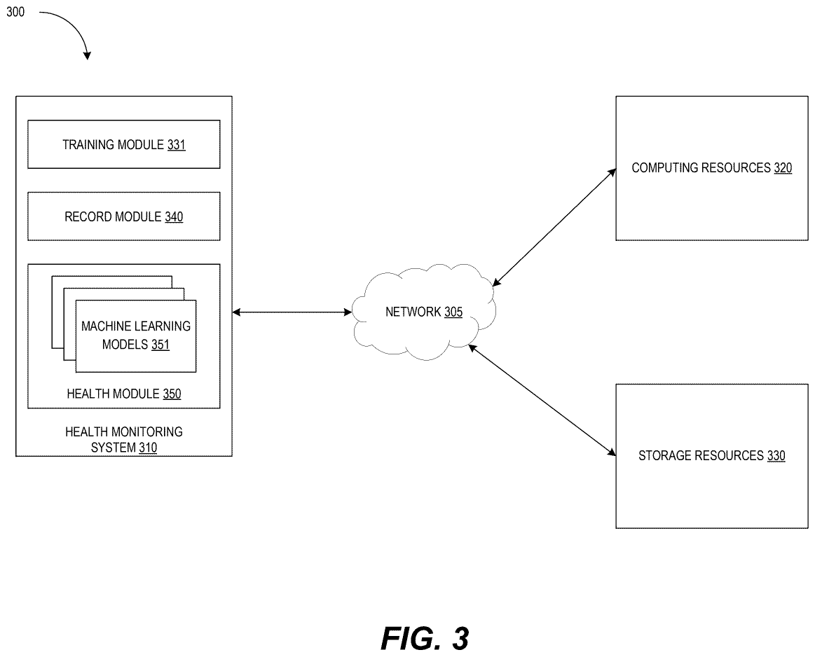

The embodiments, implementations, and/or examples, described herein may allow a health module (e.g., health module 250 illustrated in FIGS. 2-3) and/or a battery management system (e.g., the battery management system 120 illustrated in FIGS. 1-2) to determine an estimated health (e.g., estimated state of health, a state of health, etc.) based on charging events that may be inconsistent and/or random, as discussed in more detail below. By using a machine learning model for each state of charge range, the health module may be able to determine an estimated health of the power source regardless of which state of charge ranges were included in a particular charging event. For example, by using the machine learning models associated with the state of charge ranges that were included, covered, encompassed, etc., (e.g., fully covered) by a particular charging event, the health module may be able to determine an estimated health for the power source even if it may be unpredictable which state of charge ranges will be covered during the charging event.

Although the present disclosure may refer to batteries (e.g., lithium-ion batteries or batteries using other battery chemistries) and vehicles, the examples, implementations, aspects, and/or embodiments described herein may be used with various types of power sources for various types of devices/apparatuses.

FIG. 1 is a block diagram that illustrates an example vehicle 100, in accordance with one or more embodiments of the present disclosure. In one embodiment, the vehicle 100 may be an autonomous vehicle (e.g., a self-driving vehicle). For example, the vehicle 100 may be a vehicle (e.g., car, truck, van, mini-van, semi-truck, taxi, drone, etc.) that may be capable of operating autonomously or semi-autonomously. In another embodiment, the vehicle 100 may also be a vehicle with autonomous capabilities. A vehicle with autonomous capabilities may be a vehicle that may be capable of performing some operations, actions, functions, etc., autonomously. For example, vehicle 100 may have adaptive cruise control capabilities and/or lane assist/keep capabilities. A vehicle 100 with autonomous capabilities may be referred to as a semi-autonomous vehicle.

The vehicle 100 may include various systems that allow the vehicle 100 to operate specific functions. For example, vehicle 100 includes a sensor system 130, a control system 140, a communication system 160, an interface system 170, a propulsion system 150, a power source 110, and a battery management system 120. In other embodiments, the vehicle 100 may include more, fewer, and/or different systems, and each system may include more, fewer, and/or different components. Additionally, the systems and/or components may be combined and/or divided in any number/possibility of arrangements.

The sensor system 130 may include one or more sensors (e.g., detectors, sensing elements, sensor devices, etc.). The one or more sensors may provide information about the operation of the vehicle 100, information about the condition of the vehicle 100, information about occupants/users of the vehicle 100, and/or information about the environment (e.g., a geographical area) where the vehicle 100 is located. The one or more sensors may be coupled to various types of communication interfaces (e.g., wired interfaces, wireless interfaces, etc.) to provide sensor data to other systems of the vehicle 100. For example, a sensor may be coupled to a storage device (e.g., a memory, a cache, a buffer, a disk drive, flash memory, etc.) and/or a computing device (e.g., a processor, an ASIC, an FPGA, etc.) via a control area network (CAN) bus (or other type of communication bus, such as a Flexray). In another example, a sensor may be coupled to a storage drive and/or a computing device via Bluetooth, Wi-Fi, etc. Examples of sensors may include, but are not limited to, tire pressure sensors, steering sensors (e.g., to determine the positions/angles of one or more wheels), a compass, temperature sensors, a global positioning system (GPS) receiver/sensor, a light detection and ranging (LIDAR) device/sensor, an ultrasonic device/sensor, a camera (e.g., a video camera), a radar device/sensor, etc.

The control system 140 may include hardware, software, firmware, or a combination thereof that may control the functions, operations, actions, etc., of the vehicle 100. For example, the control system 140 may be able to control a braking system and/or an engine to control the speed and/or acceleration of the vehicle 100. In another example, the control system 140 may be able to control a steering system to turn the vehicle 100 left or right. In a further example, the control system 140 may be able to control the headlights or an all-wheel drive (AWD) system of the vehicle 100 based on weather/driving conditions (e.g., if the environment has snow/rain, if it is nighttime in the environment, etc.). The control system 140 may use sensor data and/or outputs generated by machine learning models to control the vehicle 100.

The control system 140 may use outputs generated one or more machine learning models to control the vehicle. For example, control system 140 may generate one or more steering commands based on the outputs of a machine learning model (e.g., based on objects detected by a machine learning model). The steering command may indicate the direction that a vehicle 100 should be turned (e.g., left, right, etc.) and may indicate the angle of the turn. The control system 140 may actuate one or more mechanisms/systems (e.g., a steering system, a steering wheel, etc.) to turn the vehicle 100 (e.g., to control the vehicle 100) based on the steering command. For example, the control system 140 may actuate one or more steering mechanisms that may turn/move the wheels of the vehicle by a certain number of degrees to steer the vehicle 100. The control system 140 may also control acceleration and/or deceleration of the vehicle 100. For example, the control system 140 may use the accelerator to speed up the vehicle 100 or may use the brake to slow down the vehicle 100.

The communication system 160 may include various devices, systems, components, software, hardware, firmware, etc., that allow the vehicle 100 to communicate (e.g., transmit and/or receive data) with various networks (e.g., computer networks, communication networks, etc.) and/or devices (e.g., other vehicles, server computers, etc.). For example, the communication system 160 may include antennas, network interfaces, wireless network interfaces (e.g., cellular, Wi-Fi, Bluetooth, ZigBee, ZWave, and/or other network interfaces). The communication system 160 may also allow the vehicle 100 to communicate with other vehicles (e.g., V2V communications), with infrastructure (e.g., V2I communications), and/or with other devices/networks (e.g., V2X communications).

The interface system 170 may include various devices, systems, components, software, hardware, firmware, etc., that allow the vehicle 100 to interact with external sensors, other vehicles, external computing devices, and/or a user. For example, the interface system 170 may include buttons, knobs, dials, touch screens, microphones, cameras, and/or other devices that interact with a user, present information to a user, receive user input from a user, etc. The interface system 170 may be used to display and/or indicate a health (e.g., a state of health, SoH, etc.) of the power source 110, as discussed in more detail below.

The propulsion system 150 may include various devices, systems, components, software, hardware, firmware, etc., that may be used to move the vehicle 100. For example, the propulsion system 150 may include an engine/motor, an energy source, a transmission, and wheels/tires. The engine/motor may include any combination of an internal combustion engine, an electric motor (that can be powered by an electrical battery, fuel cell, and/or other energy storage device), and/or a steam engine.

The power source 110 may be a source of energy that provides power (e.g., energy, electricity, etc.) to various components, modules, and/or systems of the vehicle 100. For example, the power source 110 may be used to power one or more of the sensor system 130, control system 140, communication system 160, interface system 170, propulsion system 150. Examples of power sources (e.g., energy sources) may include gasoline, diesel, propane, other compressed gas-based fuels, ethanol, solar panels, batteries, and other sources of electrical power. The power source 110 may be a combination of multiple power sources (e.g., may include any combination of fuel tanks, batteries, capacitors, and/or flywheels). In one embodiment, the power source 110 may be a battery (e.g., a lithium-ion battery, an electrical battery, etc.).

The battery management system (BMS) 120 may include various devices, systems, components, software, hardware, firmware, etc., that may monitor (e.g., detect, measure, etc.) the various characteristics of the power source 110. For example, if the power source 110 is a battery, the BMS 120 may monitor characteristics (e.g., operating parameters, conditions, etc.) such as battery temperature, battery voltage, battery current, battery charging and discharging data, state of charge of the power source 110, etc. The characteristics can be stored locally in the vehicle 100 by the BMS 120. The BMS 120 can also transmit such monitored information via the communication system 160 to other devices (e.g., to a server computer, to a cloud, etc.). The BMS 120 may also regulate the operating conditions of the power source 110. For example, the BMS 120 may cool the battery temperature to within a predefined threshold temperature. The BMS 120 may further manage, regulate, control, etc., the operation and/or usage of the power source 110.

Although not illustrated in FIG. 1, the vehicle 100 may also include various computing resources and/or devices. For example, the vehicle 100 may include hardware such as processing devices (e.g., processors, central processing units (CPUs), processing cores, graphics processing units (GPUS)), memory (e.g., random access memory (RAM), storage devices (e.g., hard-disk drive (HDD), solid-state drive (SSD), etc.), and other hardware devices (e.g., sound card, video card, etc.). The vehicle 100 may also include computing devices. The computing devices may comprise any suitable type of computing device or machine that has a programmable processor including, for example, a computer. In some examples, the computing devices may include a single machine or may include multiple interconnected machines (e.g., multiple computers configured in a cluster).

Some of the embodiments described herein use the states of charge (e.g., a percentage or amount of energy in a power source, such as a battery) and current/voltage provided to a battery (e.g., the amount of current/voltage provided to the battery to charge the battery) during charging events to determine health indicators. These current, voltages, and/or states of charge may be measured and/or determined while the during the charging event, which allows for a battery management system and/or a health monitoring system to determine/calculate the health indicators based on different ranges of states of charge (e.g., different state of charge ranges) after a charging event. Different machine learning models that are associated with different storage of charge ranges may be used to determine the health indicators. For example, each machine learning model may be associated with a particular state of charge.

Although charging events may often be inconsistent and/or random (e.g., may start and end at random states of charge), the embodiments, implementations, and/or examples, described herein may allow battery management system 120 determine an estimated state of health after a charging event. By using one or more machine learning models that are associated with the state of charge ranges that were included, covered, encompassed, etc., (e.g., fully covered) by a particular charging event, the battery management system 120 may be able to determine an estimated health for the power source regardless of which state of charge ranges were covered during a charging event.

FIG. 2 is a block diagram that illustrates an example battery management system 120, in accordance with one or more embodiments of the present disclosure. The battery management system 120 includes a voltage module 210, a current module 220, a state of charge (SOC) module 230, a record module 240, a health module 250, and an interface module 260. Some or all of the modules, components, systems, engines, etc., illustrated in FIG. 2 may be implemented in software, hardware, firmware, or a combination thereof. The battery management system 120 may be part of a vehicle (e.g., vehicle 100 illustrated in FIG. 1). The battery management system 120 may monitor various characteristics of a power source used by the vehicle and/or may manage (e.g., control) the operation/usage of the power source 110 illustrated in FIG. 1.

In one embodiment, the current module 220 may determine (e.g., detect, measure, test, etc.) the amount of current that is flowing via/through the power source. For example, the current module 220 may detect/measure the amount of current that is provided to the power source (e.g., a battery). In another example, the current module 220 may detect/measure the amount of current that is drawn from the power source (e.g., the amount of current that the power source provides to a load, such as an electric motor or other component/device that uses power). The current module 220 may use one or more sensors/devices (e.g., current meters/detectors, a current probe, an ammeter, etc.) to measure the amount of current as that is provided to and/or drawn from the power source. For example, the current module 220 may use a current meter to determine the amount of current that is provided to the power source while the power source is being charged (e.g., while the power source is charged using regenerative braking or via a power plug, during a charging event, etc.). In another example, the current module 220 may use a current meter to determine the amount of current that drawn from the power source (e.g., discharged from the battery) while the vehicle is using the battery (e.g., while the vehicle is drawing power from the battery to accelerate/move the vehicle).

In one embodiment, the voltage module 210 may also determine the voltage of a current that is provided to the power source. For example, the power source (e.g., the battery) may be charged by the current provided to the power source during charging (e.g., during a charging event). The voltage module 210 may use one or more sensors/devices (e.g., voltage meters/detectors) to measure the voltage of the current as the power source is charged (e.g., charged via a power cable/connector) and/or discharged. The current that is provided to the power source and/or drawn from the power source may be represented using the following equation:

$$I = V / R \qquad ( 1 )$$

where I is the current, V is the voltage of the power source, and R is the resistance of the power source. As described herein, the voltage of the current may refer to the voltage component of the current (e.g., V in equation (1)).

In one embodiment, the SOC module 230 may determine the state of charge of the power source (e.g., a battery) of the vehicle. For example, the SOC module 230 may determine/measure how much power the battery is capable of providing at various points in time. In another example, the SOC module 230 may determine the amount of power remaining in the battery. The state of charge of the battery may be represented in various ways. For example, the state of charge may be represented using a number or percentage, where 0 (or some other appropriate minimum number) may be the lowest state of charge and 100 (or some other appropriate maximum number) may be the highest state of charge. In another example, the state of charge may be represented by the remaining power/energy in the battery in terms of watt hours, kilowatt hours, etc. The state of charge of the power source may be referred to as the SoC, SOC, etc.

In one embodiment, the SOC module 230 may determine the state of charge of the power source at the beginning of a charging event and an end of the charging event. For example, the SOC module may determine a starting time (e.g., a start time, a first time, etc.) when the charging event started (e.g., when a power supply, such as a charger plug, was connected to the power source, when power/energy starting flowing to the power source, etc.) and may determine the state of charge of the power source when the charging event started (e.g., a starting state of charge). The SOC module 230 may also determine an ending time (e.g., an end time, a second time, etc.) when the charging event ended (e.g., when a power supply, such as a charger plug, was disconnected from the power source, when power/energy stopped flowing to the power source, etc.) and may determine the state of charge of the power source when the charging event ended (e.g., an ending state of charge). The SOC module 230 may provide the starting stage of charge and the ending state of charge to the record module and the record module 240 may generate, create, store, etc., a charging record associated with the charging event, as discussed in more detail below.

In one embodiment, the record module 240 may track charging events that occur and may generate charging records for the charging events. The record module may receive information/data from the voltage module 210, the SOC module 230, the current module 220 and/or any other appropriate modules (not illustrated in FIG. 2) each time a charging event occurs. For example, the record module 240 may receive data indicating voltages (e.g., a voltage of a current, voltages within components of the power source), currents (e.g., an amount of current provided to the power source), states of charge (e.g., a starting state of charge and an ending state of charge) each time a charging event occurs. The record module 240 may generate charging records (e.g., records, entries, logs, etc.) for each charging event and may store the charging records (e.g., in a memory, on a storage system, on a cloud storage service, etc.) for later use.

In one embodiment, the charging records may be associated, arranged, organized, etc., based on state of charge ranges (e.g., a range of states of charge). The state of charge of the power source may range from 0 to 100%. The total range of the state of charge of the power source may be divided into smaller ranges. For example, 0% to 10% may be a first state of charge range, 11% to 20% may be a second state of charge range, 21% to 30% may be a third state of charge range, etc. Different embodiments may use different state of charge ranges. For example, the total range of state of charge may be divided into twenty ranges (e.g., with each range representing 5% of the state of charge), one hundred ranges (e.g., with each range representing 1%), two hundred ranges (e.g., with each range represent 0.5%), or any appropriate number of ranges. Each charging record may include information for a charging event (e.g., current, voltage, temperature, vehicle mileage, etc.) for a particular state of charge range. For example, a charging record may include the amount of current provided to the power source, voltages, temperatures, etc., for a first state of charge range (e.g., from 11-20%).

As illustrated in FIG. 2, the health module 250 may include machine learning models 251. Each machine learning model 251 may be associated with a particular range of states of charge. As discussed above, the total range for the state of charge of the power source may be divided into multiple smaller ranges (e.g., ranges of 10% each). The health module 250 may include one machine learning model 251 associated with each of the multiple ranges (e.g., each of the multiple state of charge ranges). For example, if the total range for the state of charge is divided into ten ranges (of 10% each), there may be ten machine learning models 251, one for each state of charge range.

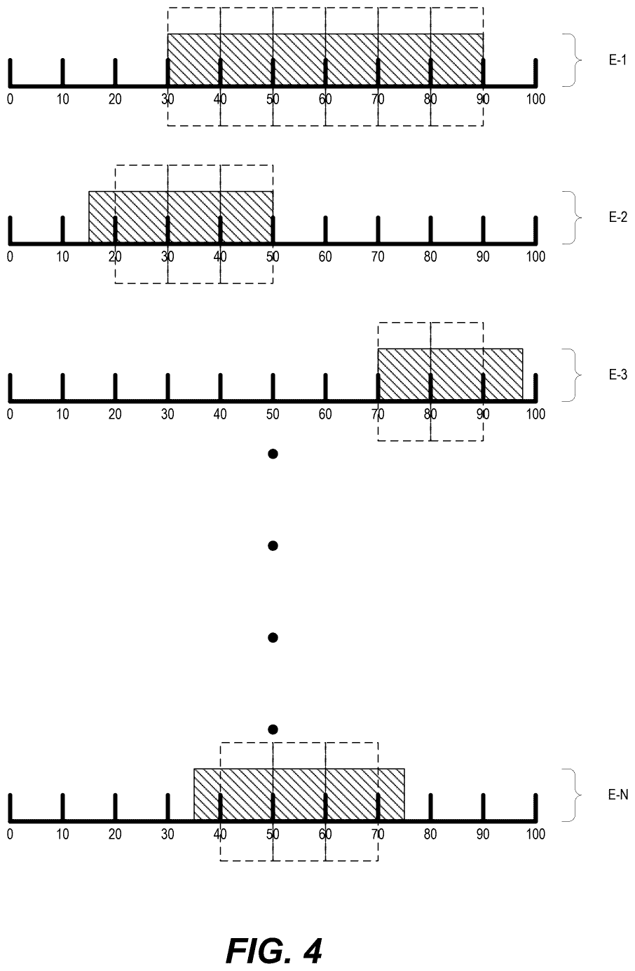

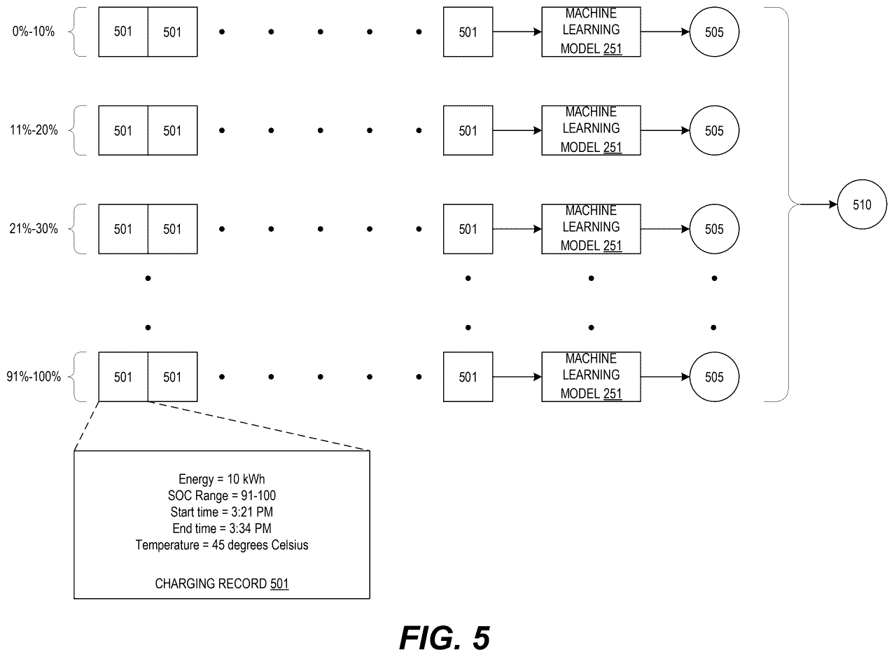

In one embodiment, after a charging event, the health module 250 may identify a set of state of charge ranges based on the beginning state of charge and the ending state of charge for the charging event. For example, one or more state of charge ranges may be identified based on how many state of charge ranges are covered, included, encompassed, etc., by the beginning state of charge and the ending state of charge, as discussed in more detail below in FIGS. 4 and 5.

In one embodiment, the health module 250 may identify a set of machine learning models 251 based on the identified set of charge ranges. For example, if the health module 250 identifies two state of charge ranges that are included in a charging event (e.g., a first state of charge range going form 11% to 20% and a second state of charge range going from 21%-30%), the health module 250 may identify, select, etc., two machine learning models 251. The first machine learning model 251 may be associated with the first state of charge and the second machine learning model 251 may be associated with the second state of charge range.

In one embodiment, the health module 250 may determine an estimated health (e.g., an estimated state of health) for the power source based on the identified set of machine learning models. For example, if a charging event includes three state of charge ranges and three machine learning models 251 are identified/selected, the health module 250 may use the (selected) three machine learning models 251 to determine, calculate, etc., an estimated health for the power source. The health module 250 may provide all of the charging records associated with the three state of charge ranges to the three machine learning models 251. For example, all charging records that are associated with the first state of charge range may be provided to the first machine learning model 251, all charging records that are associated with the second state of charge range may be provided to the second machine learning model 251, and all charging records that are associated with the third state of charge range may be provided to the third machine learning model 251.

In one embodiment, the health module 250 may use or select all of the machine learning models 251 to determine an estimated health of the power source, regardless of whether a charging event encompasses, includes, etc., the state of charge range associated with a machine learning model. For example, if there are ten machine learning models 451 and only three state of charge ranges were included in a charging event, the health module 250 may still use all ten machine learning models 251 to determine the estimated health. All of the charging records associated with each state of charge range may be provided to the respective machine learning model for that state of charge range.

In one embodiment, each machine learning model 251 that is used, selected, identified, etc., may generate, output, calculate, determine, etc., a health indicator based on a set of charging records (e.g., one or more charging records). For example, each machine learning model 251 (that is selected/identified for use) may be provided the respective set of charging records for the respective state of charge range. Each machine learning model 251 may output a health indicator (or some other value that may be used to determine, calculate, etc., the health of the power source) based on the respective set of charging records. The health module 250 may use the health indicators generated by the selected/identified machine learning models 251 to determine the estimated health of the power source, as discussed in more detail below.

In one embodiment, the health module 250 may determine the estimated health by determining an average health indicator. For example, each selected/identified machine learning model 251 may generate a health indicator, as discussed above. The health module 250 may determine an average health indicator based on the sum of the health indicators generated by the selected/identified machine learning model 251.

In one example, the health module 250 may determine the estimated health by determining a weighted average health indicator. Certain health indicators (which are generated by certain machine learning models 251) may be given more weight when determining the weighted average health indicator. For example, some machine learning models 251 that may have been trained with more training data than other machine learning models 251. The health indicators generated by machine learning models 251 that were trained with more training data, may be given more weight in the weighted average health indicator. Various parameters, criteria, conditions, etc., for weighting a health indicator generated by a particular machine learning model 251 may be used in other embodiments.

In one embodiment, the health module 250 may determine the estimated health using an additional machine learning model (not illustrated in FIG. 2). For example, one or more health indicators may be provided to the additional machine learning model and the additional machine learning model may generate, compute, calculate, etc., the estimated health of the power source based on the one or more health indicators.

In one embodiment, the health indicator may be an indication of the amount of degradation in the capacity (e.g., storage capacity) of the power source (e.g., the battery). For example, a lower health indicator may indicate more/higher degradation in the capacity of the power source, or vice versa.

In one embodiment, the functions, formulas, correlations, etc., between the health indicators and the estimated health of the battery may be determined based on experimentation and/or testing with different types of power sources (e.g., different battery packs with different chemistries). For example, a previous battery (e.g., battery pack) may have been charged and discharged, and health indicators may have been calculated/determined based on previous charging events for the previous battery. The health indicators (for different states of charge) at different ages of the previous battery may be recorded in table, list, or some other appropriate data structure. The health indicators for the previous battery may be referred to as reference health indicators. The health module 250 may use the reference health indicators to determine the health of the power source based on the health indicators obtained while the power source is charging (e.g., during a charging event). Different sets of reference health indicators may be determined for different types of battery packs. For example, a set of reference health indicators may be determined for each configuration/combination of cells, battery chemistries, capacities, etc., for a battery pack.

In one embodiment, the health of the power source may be determined based on various functions, formulas, correlations, etc., between one or more health indicators and the health of the battery. For example, a ten percent change (e.g., increase or decrease) in a first health indicator may correlate to a five percent decrease in battery health. The correlation between the one or more health indicators and the health of the battery may be represented using various functions, formulas, etc. For example, the correlation between the health indicator may be represented using one or more of a linear function, multiple piecewise linear functions, an exponential function, a polynomial function, a quadratic function, a logarithmic function, etc.

In one embodiment, the interface module 260 may provide an indication of the health of the power source to an interface system (e.g., interface system 170 illustrated in FIG. 1). For example, the interface module 260 may transmit a message indicating the health of the power source to the interface system based on an estimated health generated, calculated, determined, etc., by the health module 250. The interface module 260 may provide the estimated health and/or other information/data to a user (e.g., via one or more screens, displays, touch screens, etc.). The interface system may also receive user input (e.g., via buttons, touchscreens, etc.) that may allow the user to control the operation of the vehicle.

FIG. 3 is a block diagram that illustrates an example system architecture 300, in accordance with some embodiments of the present disclosure. The system architecture 300 includes network 305, a health monitoring system 310, computing resources 320, and storage resources 330. Network 305 may interconnect the health monitoring system 310, the computing resources 320, and/or the storage resources 330. Network 305 may be a public network (e.g., the internet), a private network (e.g., a local area network (LAN) or wide area network (WAN)), or a combination thereof. In one embodiment, network 305 may include a wired or a wireless infrastructure, which may be provided by one or more wireless communications systems, such as a wireless fidelity (Wi-Fi) hotspot connected with the network, a cellular system, and/or a wireless carrier system that can be implemented using various data processing equipment, communication towers (e.g. cell towers), etc. Network 305 may carry communications (e.g., data, message, packets, frames, etc.) between the health monitoring system 310, the computing resources 320 and/or the storage resources 330.

The computing resources 320 may include computing devices which may include hardware such as processing devices (e.g., processors, central processing units (CPUs), processing cores, graphics processing units (GPUS)), memory (e.g., random access memory (RAM), storage devices (e.g., hard-disk drive (HDD), solid-state drive (SSD), etc.), and other hardware devices (e.g., sound card, video card, etc.). The computing devices may comprise any suitable type of computing device or machine that has a programmable processor including, for example, server computers, desktop computers, rackmount servers, etc. In some examples, the computing devices may include a single machine or may include multiple interconnected machines (e.g., multiple servers configured in a cluster, cloud computing resources, etc.).

The computing resources 320 may also include virtual environments. In one embodiment, a virtual environment may be a virtual machine (VM) that may execute on a hypervisor which executes on top of the OS for a computing device. The hypervisor may also be referred to as a virtual machine monitor (VMM). A VM may be a software implementation of a machine (e.g., a software implementation of a computing device) that includes its own operating system (referred to as a guest OS) and executes application programs, applications, software. The hypervisor may be a component of an OS for a computing device, may run on top of the OS for a computing device, or may run directly on host hardware without the use of an OS. The hypervisor may manage system resources, including access to hardware devices such as physical processing devices (e.g., processors, CPUs, etc.), physical memory (e.g., RAM), storage device (e.g., HDDs, SSDs), and/or other devices (e.g., sound cards, video cards, etc.). The hypervisor may also emulate the hardware (or other physical resources) which may be used by the VMs to execute software/applications. The hypervisor may present other software (i.e., “guest” software) the abstraction of one or more virtual machines (VMs) that provide the same or different abstractions to various guest software (e.g., guest operating system, guest applications). A VM may execute guest software that uses an underlying emulation of the physical resources (e.g., virtual processors and guest memory).

In another embodiment, a virtual environment may be a container that may execute on a container engine which executes on top of the OS for a computing device, as discussed in more detail below. A container may be an isolated set of resources allocated to executing an application, software, and/or process independent from other applications, software, and/or processes. The host OS (e.g., an OS of the computing device) may use namespaces to isolate the resources of the containers from each other. A container may also be a virtualized object similar to virtual machines. However, a container may not implement separate guest OS (like a VM). The container may share the kernel, libraries, and binaries of the host OS with other containers that are executing on the computing device. The container engine may allow different containers to share the host OS (e.g., the OS kernel, binaries, libraries, etc.) of a computing device. The container engine may also facilitate interactions between the container and the resources of the computing device. The container engine may also be used to create, remove, and manage containers.

The storage resources 330 may include various different types of storage devices, such as hard disk drives (HDDs), solid state drives (SSD), hybrid drives, storage area networks, storage arrays, etc. The storage resources 330 may also include cloud storage resources or platforms which allow for dynamic scaling of storage space.

Although the computing resources 320 and the storage resources 330 are illustrated separate from the health monitoring system 310, one or more of the computing resources 320 and the storage resources 330 may be part of the health monitoring system 310 in other embodiments. For example, the health monitoring system 310 may include both the computing resources 320 and the storage resources 330.

As illustrated in FIG. 3, the health monitoring system 310 includes a training module 331, health module 350, and record module 340. The health module 350 includes machine learning models 351. In one embodiment, the health module 350, the machine learning models 351, and the record module 340 may perform functions, operations, actions, similar to health module 250, machine learning models 251, and record module 340 illustrated in FIG. 2. For example, health module 350 may determine, generate, calculate, etc., an estimated health for a power source based one or more machine learning models 351 and one or more charging records. In another example, record module 340 may obtain currents, voltages, temperatures, and/or other information related to charging events from a vehicle/device, and may generate charging records that are used by the machine learning models 351.

As discussed above, although charging events may often be inconsistent and/or random (e.g., may start and end at random states of charge), the health module 250 may be able to determine an estimated state of health after a charging event. By using one or more machine learning models 351 that are associated with the state of charge ranges that were included, covered, encompassed, etc., (e.g., fully covered) by a particular charging event, the health module 350 may be able to determine an estimated health for the power source regardless of which state of charge ranges were covered during a charging event.

In one embodiment, the training module 331 may be used to train one or more of the machine learning models 351. For example, the training module 331 may train one or more of the machine learning models 351 (and/or the machine learning models 251 illustrated in FIG. 2), based on training data that includes training charging records and expected health indicators for the training charging records.

FIG. 4 is a diagram that illustrates example charging events E-1 through E-N, in accordance with some embodiments of the present disclosure. As discussed above, a charging event may refer to an event, occurrence, period of time, etc., when power/energy is being provided to a power source (e.g., a battery). In the example illustrated in FIG. 4, the total range of the state of charge of the charge may be divided into ten ranges, with each range included 10% of the total range. For example, the total range of 0% to 100% is divided into 10 ranges of 10% each (e.g., 0% to 10%, 11% to 20%, 21% to 30%, etc.).

The beginning (e.g., starting) state of charge, and ending state of charge are illustrated for each charging event (e.g., illustrated by the shaded rectangles). For example, for charging event E-1, the beginning state of charge for the power source was 30% and the ending state of charge for the power source was 90%. In another example, for charging event E-2, the beginning start of charge was 15% and the ending state of charge was 50%. In a further example, for charging event E-3, the beginning state of charge was 70% and the ending state of charge was 97%.

As discussed above, a record module (e.g., record module 240 illustrated in FIG. 2) may generate one or more charging records (e.g., a set of charging records) for a charging event. For example, for charging event E-1, the record module may generate (e.g., create, store), etc., six charging records, one for the 31%-40% state of charge range, one for the 41%-50% state of charge range, and so on until the 81%-90% state of charge range. For charging event E-2, the record module may generate three charging records, one for the 21%-30% state of charge range, one for the 31%-40% state of charge range, and one for the 41%-50% state of charge range.

In one embodiment, the record module may not create charging records for state of charge ranges that are partially covered, included, etc., in a charging event. For example, although the beginning state of charge for charging event E-2 was 15%, no charging record is created for the 11-20% state of charge range because the charge event E-2 did not cover, encompass, included, etc. the full 11-20% state of charge range. Similarly, no charging record may be generated for 91%-100% state of charge range for charging event E-3, and no charging record may be generated for the 31%-40% and 71-80% state of charge ranges for charging cycle E-N.

As illustrated in FIG. 4, the charging events may include, encompass, cover, etc., inconsistent state of charge ranges. For example, a user may start charging the power source at random states of charge. In addition, users may only partially charge a power source (e.g., may not charge to 100%) and/or may not consistently charge up to a same state of charge (e.g., may not always charge up to 90%). For example, a user may only charge the power source (e.g., a battery of an electric vehicle) while the user is at a location (e.g., a grocery store or a shopping mall). Because the time, duration, and states of charge for different charging events may be inconsistent and/or random, it may be difficult to compute health indicators for different charging events.

The embodiments, implementations, and/or examples, described herein may allow a health module (e.g., health module 250 illustrated in FIGS. 2-3) and/or a battery management system (e.g., battery management system 120 illustrated in FIGS. 1-2) to determine an estimated state of health with the inconsistent and/or random charging events, as discussed in more detail below. By using a machine learning model for each state of charge range, the health module may be able to determine an estimated health of the power source regardless of which state of charge ranges were included in a particular charging event. For example, by using the machine learning models associated with the state of charge ranges that were included, covered, encompassed, etc., (e.g., fully covered) by a particular charging event, the health module may be able to determine an estimated health for the power source even if it may be unpredictable which state of charge ranges will be covered during a charging event.

FIG. 5 is a diagram illustrating example charging records 501, in accordance with some embodiments of the present disclosure. As discussed above, a record module (e.g., record module 240 illustrated in FIG. 2) may generate one or more charging records 501 for each charging event. A health module (e.g., health module 250 illustrated in FIGS. 2 and 3) may use the charging records 501 to determine an estimated health for a power source (e.g., a battery of a vehicle).

In one embodiment, each charging record 501 may indicate a particular state of charge range associated with the charging records 501. For example, as illustrated in the bottom left charging record 501, the charging record 501 indicates that the charging record is associated with the 91%-100% state of charge range. All of the charging records 501 in the bottom row will also include an entry, field, etc., indicating that those charging records 501 are associated with the 91%-100% state of charge range.

In one embodiment each charging record 501 may also indicate an amount of energy or power that was provided to the power source during the charging event for a particular state of charge range. For example, for each charging event and each state of charge range, a particular amount of current at a particular voltage may be provided to the power source. The health module may compute, determine, calculate, etc., the amount of power for a particular state of charge range based on equation (2) below.

$$P = V \cdot I \qquad ( 2 )$$

P represents the power, I represents the current provided to the power source, and V represent the voltage of the current I. The health module may also determine, calculate, compute, etc., the amount of energy that provided to the power source for the particular state of charge range based on equation (3).

$${E}_{{\overline{SOC}}_{1}}^{{\overline{SOC}}_{2}} = {\int }_{{\overline{SOC}}_{1}}^{{\overline{SOC}}_{2}} V \cdot I dSOC \qquad ( 3 )$$

$${E}_{{\overline{SOC}}_{1}}^{{\overline{SOC}}_{2}}$$

represents the amount of enegy provided to the power source for the state of charge range going from SOC1 to SOC2 (e.g., from 11% to 20%, from 21% to 25%, or any other appropraite range.

$${\int }_{{\overline{SOC}}_{1}}^{{\overline{SOC}}_{2}} V \cdot I dSOC$$

represent the integration over time of the power P (e.g., V*I). Each charging record 501 may include the amount of enegy provided to the power source for the state of charge range (e.g.,

$${E}_{{\overline{SOC}}_{1}}^{{\overline{SOC}}_{2}} ) .$$

Also as illustrated in FIG. 5, each charging record 501 may also include one or more other operating parameters for the power source. For example, the charging record 501 may include a start time and end time for a particular state of charge range (e.g., a start time when state of charge of the power source matched the beginning of the state of charge range and an end time when the state of charge of the power source matched the end of the state of charge range). In another example, the temperature (or a range of temperatures) of the power source for the state of charge range may also be included.

As discussed above, the charging records 501 for one or more state of charge ranges may be provided to one or more machine learning models associated with the state of charge ranges. For example, if a power source was charged from 15% to 30%, the charging records 501 for the 11%-20% state of charge range (e.g., the second row of charging records 501 from the top) may be provided to the second machine learning model 251 (from the top) and the charging records 501 for the 21%-30% state of charge range (e.g., the third row of charging records 501 from the top) may be provided to the third machine learning model 251 (from the top).

In one embodiment, the charging records 501 may store a complete history of charging events for the power source. For example, the record module may store charging records for every charging event since the power source was installed in a device (e.g., a vehicle). In another embodiment, the charging records 501 may store a history of charging events for a period of time. For example, charging records for charging events in the last five years, one year, five months, etc., may be stored. In a further embodiment, the charging records 501 may store a history for a certain number of charging events. For example, charging records for the last one hundred, last fifty, etc., charging events may be stored.

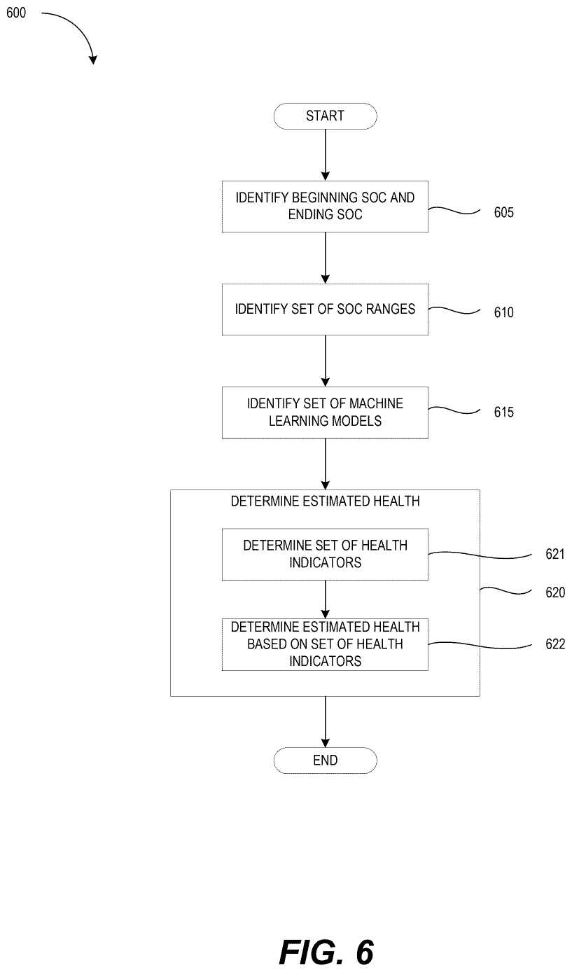

FIG. 6 is a flow diagram of a method 600 for determining an estimated health of a power source (e.g., a battery), in accordance with one or more embodiments of the present disclosure. Method 600 may be performed by processing logic that may comprise hardware (e.g., circuitry, dedicated logic, programmable logic, a field programmable gate array (FPGA), an application specific integrated circuit (ASIC), a processor, a processing device, a central processing unit (CPU), a system-on-chip (SoC), etc.), software (e.g., instructions running/executing on a processing device), firmware (e.g., microcode), or a combination thereof. In some embodiments, the method 600 may be performed by a computing device (e.g., a server computer, a desktop computer, etc.), a health module (e.g., health module 250/350 illustrated in FIGS. 2-3), a battery management system (e.g., battery management system 120 illustrated in FIGS. 1-2), and/or various components, modules, systems, etc., of the battery management system (as illustrated in FIG. 2).

With reference to FIG. 6, method 600 illustrates example functions used by various embodiments. Although specific function blocks (“blocks”) are disclosed in method 600, such blocks are examples. That is, embodiments are well suited to performing various other blocks or variations of the blocks recited in method 600. It is appreciated that the blocks in method 600 may be performed in an order different than presented, and that not all of the blocks in method 600 may be performed, and other blocks (which may not be included in FIG. 6) may be performed between the blocks illustrated in FIG. 6.

The method 600 begins at block 605 where the method 600 may identify a beginning state of charge and an ending state of charge for a charging event. For example, the method 600 may determine/identify the state of charge when the power source started charging and the state of charge when the power source stopped charging. At block 610, the method 600 may identify a set of state of charge ranges. For example, the full state of charge range (e.g., 0%-100%) may be divided into ten ranges of 10% each, twenty ranges of 5% each, or any appropriate number of ranges. The method 600 may identify which state of charge ranges were included in the charging event. For example, the method 600 may identify state of charge ranges that were fully included in the charging event.

A block 615, the method 600 may include identifying a set of machine learning models based on the set of state of charge range. For example, for each state of charge range that was identified (in block 610), the method 600 may identify machine learning model that is associated with that state of charge range. At block 620, the method 600 may include determining an estimated health for the power source. For example, the method 600 may determine a set of health indicated based on the set of machine learning models. In particular, the method 600 may perform blocks 621 and 622 to determine the estimated health of the power source.

As discussed above, a plurality of charging records may be stored for charging events that occur. Each charging record may be associated with a particular state of charge range. The method 600 may provide all of the charging records associated with each state of charge range to the machine learning model that is associated with that particular state of charge range. Each of the machine learning models may generate a corresponding health indicator at block 621. At block 622, the method 600 may include determine the estimated health based on the set of health indicators. For example, the method 600 may include determining an average or a weighted average of the set of health indicators. In another example, the method 600 may include using another machine learning model to determine the estimated health based on the set of health indicators.

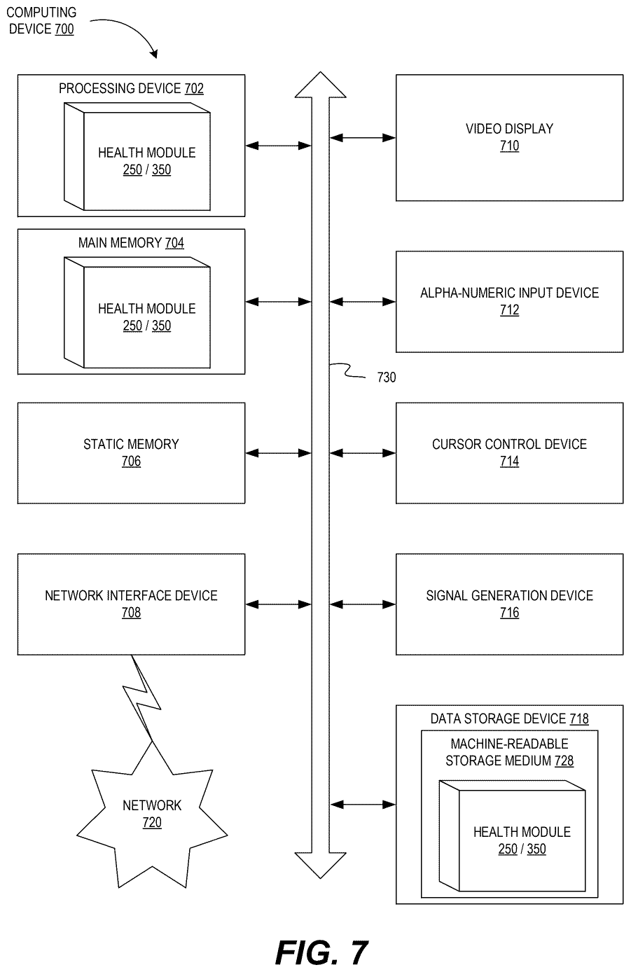

FIG. 7 is a block diagram of an example computing device 700 that may perform one or more of the operations described herein, in accordance with some embodiments. Computing device 700 may be connected to other computing devices in a LAN, an intranet, an extranet, and/or the Internet. The computing device may operate in the capacity of a server machine in client-server network environment or in the capacity of a client in a peer-to-peer network environment. The computing device may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computing device” shall also be taken to include any collection of computing devices that individually or jointly execute a set (or multiple sets) of instructions to perform the methods discussed herein.

The example computing device 700 may include a processing device 702 (e.g., a general purpose processor, a PLD, etc.), a main memory 704 (e.g., synchronous dynamic random access memory (DRAM), read-only memory (ROM)), a static memory 706 (e.g., flash memory and a data storage device 718), which may communicate with each other via a bus 730.

Processing device 702 may be provided by one or more general-purpose processing devices such as a microprocessor, central processing unit, or the like. In an illustrative example, processing device 702 may comprise a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 702 may also comprise one or more special-purpose processing devices such as an application specific integrated circuit (ASIC), a field programmable gate array (FPGA), a digital signal processor (DSP), network processor, or the like. The processing device 702 may be configured to execute the operations described herein, in accordance with one or more aspects of the present disclosure, for performing the operations and steps discussed herein.

Computing device 700 may further include a network interface device 708 which may communicate with a network 720. The computing device 700 also may include a video display unit 710 (e.g., a liquid crystal display (LCD) or a cathode ray tube (CRT)), an alphanumeric input device 712 (e.g., a keyboard), a cursor control device 714 (e.g., a mouse) and an acoustic signal generation device 716 (e.g., a speaker). In one embodiment, video display unit 710, alphanumeric input device 712, and cursor control device 714 may be combined into a single component or device (e.g., an LCD touch screen).

Data storage device 718 may include a computer-readable storage medium 728 on which may be stored one or more sets of instructions, e.g., instructions for carrying out the operations described herein, in accordance with one or more aspects of the present disclosure. Instructions implementing the different systems described herein (e.g., health module 250, health module 350, battery management system 120 and/or various components, modules, systems, etc., as illustrated in FIGS. 1-3) may also reside, completely or at least partially, within main memory 704 and/or within processing device 702 during execution thereof by computing device 700, main memory 704 and processing device 702 also constituting computer-readable media. The instructions may further be transmitted or received over a network 720 via network interface device 708.

While computer-readable storage medium 728 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding or carrying a set of instructions for execution by the machine and that cause the machine to perform the methods described herein. The term “computer-readable storage medium” shall accordingly be taken to include, but not be limited to, solid-state memories, optical media and magnetic media.

Unless specifically stated otherwise, terms such as “generating,” “determining,” “measuring,” “adjusting,” “dividing,” “requesting,” “providing,” or the like, refer to actions and processes performed or implemented by computing devices that manipulates and transforms data represented as physical (electronic) quantities within the computing device's registers and memories into other data similarly represented as physical quantities within the computing device memories or registers or other such information storage, transmission or display devices. Also, the terms “first,” “second,” “third,” “fourth,” etc., as used herein are meant as labels to distinguish among different elements and may not necessarily have an ordinal meaning according to their numerical designation.

Examples described herein also relate to an apparatus for performing the operations described herein. This apparatus may be specially constructed for the required purposes, or it may comprise a general purpose computing device selectively programmed by a computer program stored in the computing device. Such a computer program may be stored in a computer-readable non-transitory storage medium.

The methods and illustrative examples described herein are not inherently related to any particular computer or other apparatus. Various general purpose systems may be used in accordance with the teachings described herein, or it may prove convenient to construct more specialized apparatus to perform the required method steps. The required structure for a variety of these systems will appear as set forth in the description above.

The above description is intended to be illustrative, and not restrictive. Although the present disclosure has been described with references to specific illustrative examples, it will be recognized that the present disclosure is not limited to the examples described. The scope of the disclosure should be determined with reference to the following claims, along with the full scope of equivalents to which the claims are entitled.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A method, comprising:
identifying a beginning state of charge and an ending state of charge for a charging event for a battery;
identifying a set of state of charge ranges based on the beginning state of charge and the ending state of charge;
identifying a set of machine learning models based on the set of state of charge ranges, wherein each machine learning model is associated with a respective state of charge range; and
determining an estimated health for the battery based on the set of machine learning models and one or more sets of charging records for the battery.

2. The method of claim 1, wherein each set of charging records corresponds to one of set of the state of charge ranges.

3. The method of claim 2, wherein each charging record indicates an amount of energy received by the battery for a respective stage of charge range during a respective charging event.

4. The method of claim 3, wherein each charging record further includes one or more respective operating parameters of the battery during the respective charging event.

5. The method of claim 1, wherein determining the estimated health for the battery comprises:
determining the estimated health based on a set of health indicators generated by the set of machine learning models based on the one or more sets of charging records.

6. The method of claim 5, wherein determining the estimated health for the battery comprises:
determining, for each state of charge range, a respective health indicator based on a respective set of charging records and a respective machine learning model.

7. The method of claim 5, wherein determining the estimated health further comprises:
determining an average health indicator based on the set of health indicators.

8. The method of claim 5, wherein determining the estimated health further comprises:
determining the estimated health based on an additional machine learning model and the set of health indicators.

9. The method of claim 1, further comprising:
tracking a plurality of previous charging events;
generating the one or more sets of charging records based on the plurality of previous charging events; and
storing the one or more sets of charging records, wherein the one or more sets of charging records comprises a first record associated with the charging event.

10. The method of claim 1, further comprising:
providing an indication of the estimated health to one or more of an interface system or a vehicle.

11. An apparatus, comprising:
a memory configured to store data; and
a processing device coupled to the memory,
identify a beginning state of charge and an ending state of charge for a charging event for a battery;
identify a set of state of charge ranges based on the beginning state of charge and the ending state of charge;
identify a set of machine learning models based on the set of state of charge ranges, wherein each machine learning model is associated with a respective state of charge range; and
determine an estimated health for the battery based on the set of machine learning models and one or more sets of charging records for the battery.

12. The apparatus of claim 11, wherein each set of charging records corresponds to one of set of the state of charge ranges.

13. The apparatus of claim 12, wherein each charging record indicates an amount of energy received by the battery for a respective stage of charge range during a respective charging event.

14. The apparatus of claim 13, wherein each charging record further includes one or more respective operating parameters of the battery during the respective charging event.

15. The apparatus of claim 11, wherein determining the estimated health for the battery comprises:
determining the estimated health based on a set of health indicators generated by the set of machine learning models based on the one or more sets of charging records.

16. The apparatus of claim 15, wherein determining the estimated health for the battery comprises:
determining, for each state of charge range, a respective health indicator based on a respective set of charging records and a respective machine learning model.

17. The apparatus of claim 15, wherein determining the estimated health further comprises:
determining an average health indicator based on the set of health indicators.

18. The apparatus of claim 15, wherein determine the estimated health further comprising:
determining the estimated health based on an additional machine learning model and the set of health indicators.

19. The apparatus of claim 11, further comprising:
tracking a plurality of previous charging events;
generating the one or more sets of charging records based on the plurality of previous charging events; and
storing the one or more sets of charging records, wherein the one or more sets of charging records comprises a first record associated with the charging event.

20. A non-transitory computer-readable storage medium including instructions that, when executed by a processing device, cause the processing device to:
identify a beginning state of charge and an ending state of charge for a charging event for a battery;
identify a set of state of charge ranges based on the beginning state of charge and the ending state of charge;
identify a set of machine learning models based on the set of state of charge ranges, wherein each machine learning model is associated with a respective state of charge range; and
determine an estimated health for the battery based on the set of machine learning models and one or more sets of charging records for the battery.
